(19) United States
(12) Patent Application Publication
(10) Pub. No.: US 2005/0030898 A1
(43) Pub. Date: Feb. 10, 2005

(54) Using inter-packet gap as management channel

(75) Inventors: Darrell Furlong, Hollis, NH (US); Brain Cole, Nashua, NH (US); Gregory Carlson, North Chelmsford, MA (US)

Correspondence Address: MAINE & ASMUS, 100 MAIN STREET, P O BOX 3445, NASHUA, NH, 03061-3445, US

(73) Assignee: Metrobility Optical Systems Inc., Merrimack, NH (US)

(21) Appl. No.: 10/852,014

(22) Filed: May 24, 2004

Related U.S. Application Data
(63) Continuation-in-part of application No. 09/566,851, filed on May 8, 2000, now Pat. No. 6,741,566.

(51) Int. Cl. G01R 31/08

(52) U.S. Cl. 370/236

(57) ABSTRACT

Ethernet, or more generally any packetized network system, remote management techniques are provided, where management instructions and data (“management packets”) are presented during the active idle signal period (e.g., during the inter-packet gap). The management packets are separated from the signalling before normal packet data processing. Thus, remote management is achieved transparently and without using payload bandwidth. Line cards, media converters, and other network devices can employ the management techniques. The management channel enables write and read commands to remote devices on the network, and alarm reporting by a remote device. Also, monitoring of remote device parameters (e.g., temperature, power status), monitoring of remote statistics, remote link testing (loopback), remote adjusting of maximum burst size, and bandwidth provisioning are enabled.

### RELATED APPLICATIONS

This application is a continuation-in-part of U.S. application Ser. No. 09/566,851, filed 8 May 2000 (U.S. Pat. No. 6,741,566), which is herein incorporated in its entirety by reference.

### FIELD OF THE INVENTION

The invention relates to network systems, and more particularly, to a remotely managed packet data system having management control information provided during non-data gaps between the data packets.

### BACKGROUND OF THE INVENTION

Prior management and control of remote network system devices, such as by simple management network protocol (SNMP) control, require the use of bandwidth that would otherwise be available for payload data and other network traffic. Moreover, conventional management and signalling protocol for such remotely-managed network devices is excessively cumbersome, unstable or otherwise undesirable. In particular, conventional management and signalling protocols for remotely controlling devices require the same high-level network operations as required for the data exchange, and may also fail to provide available network management when the system high-level network operations becomes disabled.

What is needed, therefore, are techniques for efficiently carrying out management without impacting on bandwidth available for transporting payload data and other network traffic.

### SUMMARY OF THE INVENTION

One embodiment of the present invention provides an apparatus (e.g., line card, media converter) for carrying out remote management over a network without using payload data bandwidth. The apparatus includes a first media physical layer connection device that is adapted to transmit over a first media payload data packets with inter-packet gaps therebetween. A management packet inserter module is adapted for inserting management packets into the inter-packet gaps, thereby providing a management channel for carrying out remote device management without impacting payload data bandwidth. In one such embodiment, the first media physical layer connection device is further adapted to receive remotely transmitted payload data packets with inter-packet gaps therebetween. Here, the apparatus further includes a management packet extractor module adapted for extracting management packets from the inter-packet gaps.

In another such embodiment, the apparatus enables communication between the first media (e.g., copper) and a second media (e.g., fiber). Here, the apparatus further includes a second media physical layer connection device in communication with the first media physical layer connection device. The second media physical layer connection device is adapted to transmit second media payload data packets with inter-packet gaps therebetween. In such a case, the apparatus may further include a second management packet inserter module adapted for inserting management packets into the inter-packet gaps between the second media payload data packets, thereby providing a second management channel for carrying out management of one or more remote devices associated with the second media. The second media physical layer connection device may further be adapted to receive second media payload data packets with inter-packet gaps therebetween. Here, the apparatus further includes a second management packet extractor module adapted for extracting management packets from the inter-packet gaps between the second media payload data packets.

The payload data packets and inter-packet gaps therebetween may comply, for example, with IEEE 802.3 standards, whether carrying user data, idle data, or management data. The management packet may include, for instance, a command portion that enables at least one of the following: loopback mode at a remote device, remote monitoring of statistics, alarm notification, and remote monitoring of remote device parameters. The management packet may include a command portion that enables remote monitoring of at least one of a remote device's temperature and power supplies. The management packet may include a command portion that enables remote monitoring of at least one of a remote device's transmit and receive power. The management packet may include a command portion that enables at least one of writing data to a remote device and reading data from a remote device. The management packet may include a command portion that enables at least one of bandwidth provisioning and adjustment of maximum burst size associated with a particular communication port on the network.

Another embodiment of the present invention provides an apparatus for carrying out remote management over a network without using payload data bandwidth. This particular apparatus includes a first media physical layer connection device that is adapted to transmit and receive first media payload data packets with inter-packet gaps therebetween. A second media physical layer connection device in communication with the first media physical layer connection device is also provided, which is adapted to transmit and receive second media payload data packets with inter-packet gaps therebetween. Also, one or more modules are adapted to use the inter-packet gaps to provide a management channel for carrying out remote device management without impacting payload data bandwidth.

The management channel can be used to enable alarm reporting by a remote device. The management channel can be used to enable a number of useful features and functionality. For instance, the management channel can be used to enable loopback mode at a remote device, remote monitoring of statistics, and monitoring of remote device parameters including at least one of: temperature, optical transceiver transmit power, optical transceiver receive power, and power supply voltages. The management channel can also be used to enable at least one of writing data to a remote device and reading data from a remote device. The management channel can also be used to enable at least one of bandwidth provisioning and adjustment of maximum burst size associated with a particular communication port on the network.

Another embodiment of the present invention provides an apparatus for carrying out remote management over a network without using payload data bandwidth. This particular apparatus includes a first physical layer circuit that is configured to provide access to a first management channel allocated during inter-packet gaps that exist between payload packets processed by the first physical layer circuit. Also included is a second physical layer circuit that is configured to provide access to a second management channel allocated during inter-packet gaps that exist between payload packets processed by the second physical layer circuit. Each of the first and second management channels is for carrying out remote device management without impacting payload data bandwidth. Note that the first physical layer circuit can be coupled to a first media and the second physical layer circuit can be coupled to a second media, where the apparatus operates as media converter.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1 is a diagram illustrating an exemplary network system configured in accordance with one embodiment of the present invention.

FIG. 2 is a data flow/format diagram of a network signal transfer in accordance with one embodiment of the present invention.

FIG. 3 illustrates the signalling hierarchy including the location of WAN management signalling in accordance with one embodiment of the present invention.

FIG. 4A and FIG. 4B illustrate the communication sequence between local and remote devices in accordance with one embodiment of the present invention.

FIG. 5 is a block diagram of the board level implementation configured in accordance with one embodiment of the present invention.

FIG. 6 is a block diagram of an FPGA configured in accordance with the embodiment of FIG. 5.

### DETAILED DESCRIPTION OF THE INVENTION

Embodiments of the present invention provide the ability to reach across a wide area network (WAN) to communicate, test, troubleshoot, and reconfigure an unmanaged or managed remote device, via a management channel. This management channel allows line cards, media converters, and other such physical layer interface devices to transmit and receive “management packets” on the same media that carries payload, without reducing the available bandwidth to the customer site.

The management channel is provided in applications, for example, where the communicating physical layer interface devices have programmable access to the idle bits presented during the idle period between packets, such as the inter-packet gap (IPG) described in the IEEE 802.3 standards. The idle bits can be set or otherwise manipulated to carry management data, where each set of bit defines a management packet. The management data is added after packet-based network data (e.g., Ethernet) encoding, and removed at the receiving node before network data decoding to remain transparent to normal system data transfer operation.

Various features and benefits are enabled through use of the management channel. For example, complete remote monitoring (RMON) Group 1 Ethernet statistics is enabled. The management channel also enables user selected burst size and bandwidth allocation, as well as remote link testing capability or “loopback”. The management channel also enables the remote monitoring of various parameters, such as line card temperature and voltage levels and laser transmit/receive optical power.

Commands or collection information also included in the management packet will depend on the desired management activity. The remote devices can be operated in a stateless mode, wherein responses to received commands result in a direct remote device response, thus avoiding unstable and unpredictable system operations, especially during start-up or other transient conditions. Moreover, the added network control data signalling included in the management packets does not reduce system reliability. Rather, network control of enhanced reliability is provided, since the management packets have a data format significantly shorter than the prior network data packets. Such management packets are more likely to be transferred without error.

Furthermore, note that serial nesting of remote devices along the Ethernet path is enabled, where management instructions to and data from each such remote devices are forwarded through intermediate remote devices by successive receipt and retransmission, or “hops.”

System Overview

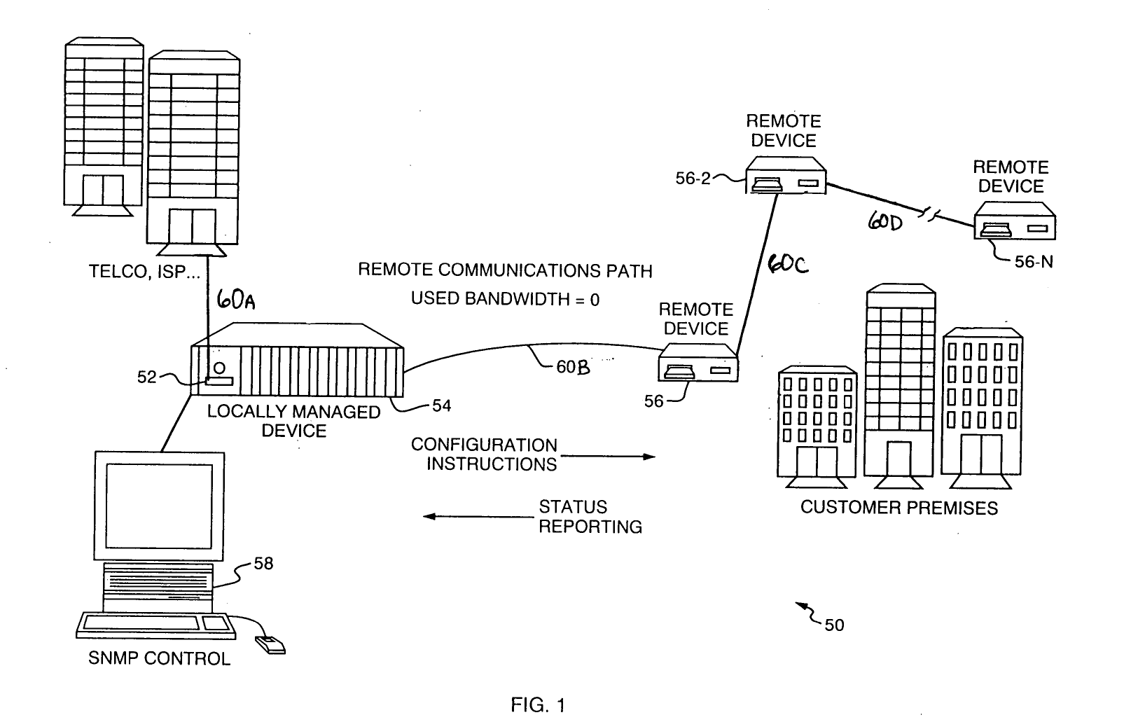

FIG. 1 is a diagram illustrating an exemplary network system configured in accordance with one embodiment of the present invention. As can be seen, the system 50 enables the network controller 52, via locally managed device 54, to reach across the network to interrogate control, status, and performance attributes of the remote network device 56. This “reach across the network” is accomplished using the inter-packet gap (IPG) that exists between and independent of the network format data packets as a management channel (e.g., IPG between Ethernet data packets). When network management is in operation via this in-media management channel, it will have no impact on the customer data or available bandwidth.

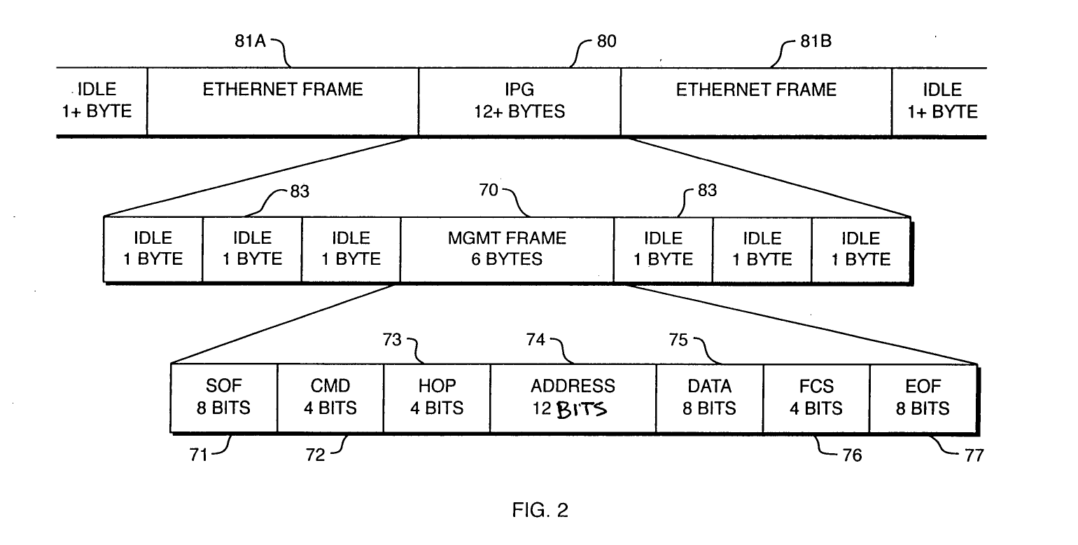

In operation, the network operator or service provider (e.g., Telco or ISP) can access the locally managed device 54 via communication link 60A to program or otherwise configure the device 54 and/or controller 52 to operate in accordance with the principles of the present invention. Likewise, each remote device 56 located at the customer premises is coupled via a communication link 60 (e.g., 60C and 60D). Another link 60B communicatively couples the locally managed device 54 and the remote device 56. The communication links 60 can generally be implemented in conventional wired (e.g., copper or fiber or cable) or wireless technology, and can be different at each location. Note that each of the remote devices 56 can be accessed via the controller 52 using a hop feature, as will be discussed in more detail with reference to FIG. 2.

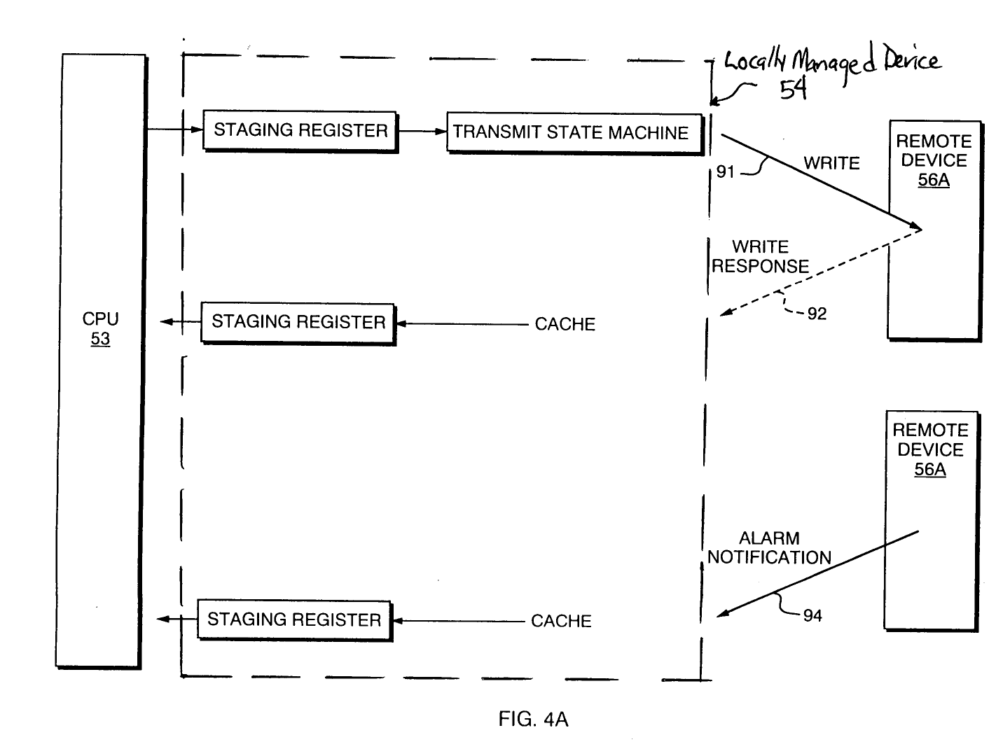

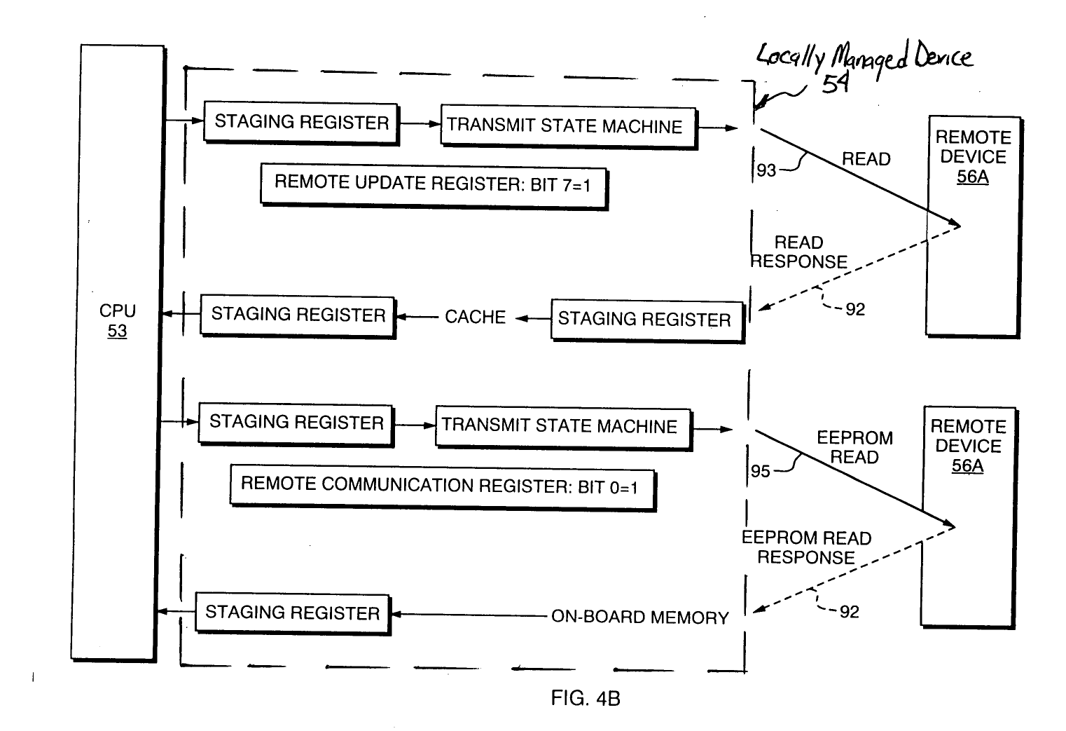

The controller 52 includes a controller CPU 53 (FIGS. 4A and 4B) and additional control, such as SNMP control via programmable system 58 or equivalent. Configuration instructions can be provided from the locally managed device 54 to the remote device 56 via the management channel. In addition, status reporting information can be provided from the remote device 56 back to the locally managed device 54 via the management channel. Note that any number of remote devices 56 (e.g., devices 56, 56-2 . . . 56-N) located at the customer premises can be accessed via the management channel, as will be apparent in light of this disclosure.

Management Channel Structure

FIG. 2 is a data flow/format diagram of a network signal transfer in accordance with one embodiment of the present invention. As can be seen, the management channel is this example uses the IPG 80, which is the idle time between Ethernet packets or “frames” 81A and 81B, etc., transmitted between network devices. Note that management packets or “frames” 70 of the IPG 80 can be transmitted at any speed that is supported by the particular protocol employed (e.g., Ethernet with active idle). Thus, the management channel can be run at line speed.

A management channel packet or frame 70 is generated to convey particular management data and commands between network devices on the network. Note that a number of idle bytes 83 included in the IPG 80 (to either side of the management packet 70) may remain unused. Further note that a network device can serve as both a master and a slave. While the master device is under local software control (e.g., SNMP control 58), the slave device can be located at some remote location (e.g., 100 km away). In one embodiment, the sending device (e.g., locally managed device 54) may initially be the master, while the receiving/responding device (e.g., remote device 56) is the slave. In other embodiments or instances in the communication protocol of a particular application, the reverse may be true (as shown in FIGS. 4A and 4B).

The structure of the management packet 70 in this example includes: eight bits to indicate the start of management packet frame (SOF) 71; four bits to specify a particular management command/response (CMD) 72; four bits to specify a hop value (HOP) 73; twelve bits to specify the address 74 (e.g., register) of the intended recipient of the management packet; eight bits to specify data 75 (e.g., data being written to register of remote device); four bits to specify a frame check sequence (FCS) 76; and eight bits to indicate the end of the management packet frame (EOF) 77. Note that the number of bits comprising the constituent bytes and/or words of the management packet 70 may vary from one protocol to the next.

Further note that the packet 70 structure provides for direct connection between a sending and receiving device, based on the address 74 and the hop value 73. For instance, the target register of each remote device 56 (each device 56 includes a similar set of addressable registers) is designated by the address 74. The specific target device 56 that is the intended recipient of the sent message is specified by the hop value 73. In more detail, the hop value 73 in the management packet 70 specifies the number of receipts and retransmissions of that packet 70. Each time the packet 70 is retransmitted, the hop value 73 is decremented by one. The process repeats until the hop value 73 is zero to indicate that the receiving remote device 56 is the final destination. Thereafter, the data in the IPG 80 is replaced by nominal IPG idle signals.

In this particular embodiment, a 4-bit hop specifier can provide up to 15 retransmissions, or hops to additional remote devices 56-2 . . . 56-N. To provide a hop example, consider the case where the hop value 73 of a management packet 70 sent by the controller 52 is set to 1 (with reference to FIG. 1). Here, the locally managed device 54 will receive the packet first, see that the hop value 73 is not zero, and therefore decrement the hop value 73 by one and forward the packet 70 to the next recipient, which in FIG. 1 is remote device 56. Remote device 56 will see that the hop value 73 is zero, thereby indicating that it is the intended recipient of the received packet 70. The register address 74 of remote device 56 will then be operated on or otherwise used based on the specified command 72.

Note that all management functions and information can be set through use of registers, which can be read by for example, an FPGA to carry out the desired management functionality. Table 1 illustrates an example memory map defining a set of registers and the corresponding management functions.

TABLE 1
Register Memory Map

| | |
|---|---|
| 0x00 | Main CSR |
| 0x01 | Product-Specific CSRs |
| 0x07 | . |
| 0x08 | Individual Port CSRs |
| 0x3F | . |
| 0x40 | Remote Communications Register |
| 0x41 | Remote Update Register |
| 0x42 | Reserved |
| 0x47 | Reserved |
| 0x48 | Upper Byte - Port 0 CSR |
| 0x4a | Bandwidth Increment Control - Port 1 |
| 0x4b | Bandwidth Increment Control - Port 0 |
| 0x4c | RESERVED |
| 0x4d | RESERVED |
| 0x4e | RESERVED |
| 0x4f | RESERVED |
| 0x49 | Upper Byte - Port 1 CSR |
| 0x50 | Software Mailbox (1 of 10) |
| 0x51 | . |
| 0x59 | Software Mailbox (10 of 10) |
| 0x5A | Not used |
| 0x5B | FPGA Version/Statistic Control Register |
| 0x5C | Port 0 BWP Adj. − |
| 0x5D | Port 0 BWP Adj. + |
| 0x5E | Port 1 BWP Adj. − |
| 0x5F | Port 1 BWP Adj. + |
| 0x60 | Laser Transmit Level - Port 0 |
| 0x61 | Laser Transmit Level - Port 1 |
| 0x62 | Discovery Counter |
| 0x63 | Remote Management Transmit Register (0) |
| 0x64 | Remote Management Transmit Register (1) |
| 0x65 | Remote Management Transmit Register (2) |
| 0x66 | Remote Management Transmit Register (3) |
| 0x67 | Remote Management Receive Register (0) |
| 0x68 | Remote Management Receive Register (1) |
| 0x69 | Remote Management Receive Register (2) |
| 0x6A | Remote Management Receive Register (3) |
| 0x6B | Alarm Register |
| 0x6E | PIC Firmware Revision |
| 0x6F | Env. Reg 1-Voltage 5.0 |
| 0x70 | Env. Reg 2-Voltage 3.3 |
| 0x71 | Env. Reg 3-Voltage 1.8 |
| 0x72 | Env. Reg 4-Internal Temperature |
| 0x73 | Laser Receive Level-Port 0 |
| 0x74 | Laser Receive Level-Port 1 |
| 0x75 | Extended Communications Control Reg |
| 0x76 | Hardware Configuration Register (0) |
| 0x77 | Channel 0, BW Provisioning Register |
| 0x78 | Management Packet Counter (0) |
| 0x79 | Management Packet Counter (1) |
| 0x7A | Management Packet Counter (2) |
| 0x7B | Management Packet Counter (3) |
| 0x7C | Channel 1, BW Provisioning Register |
| 0x7D | Link Transition Counter |
| 0x7E | Remote Discovery Register |
| 0x7F | Device ID Register |
| 0x80 | RMON MIB Port0 |
| . | . |
| . | . |
| . | . |
| 0xBF | . |
| 0xC0 | Port 0, Dropped Octets Counter (0) |
| 0xC1 | Port 0, Dropped Octets Counter (1) |
| 0xC2 | Port 0, Dropped Octets Counter (2) |
| 0xC3 | Port 0, Dropped Octets Counter (3) |
| 0xC4 | Port 0, Dropped Packets Counter (0) |
| 0xC5 | Port 0, Dropped Packets Counter (1) |
| 0xC6 | Port 0, Dropped Packets Counter (2) |
| 0xC7 | Port 0, Dropped Packets Counter (3) |
| 0xC8 | RMON MIB Port1 |
| . | . |
| . | . |
| . | . |
| 0x108 | . |
| 0x109 | Port 1, Dropped Octets Counter (0) |
| 0x10A | Port 1, Dropped Octets Counter (1) |
| 0x10B | Port 1, Dropped Octets Counter (2) |
| 0x10C | Port 1, Dropped Octets Counter (3) |
| 0x10D | Port 1, Dropped Packets Counter (0) |
| 0x10E | Port 1, Dropped Packets Counter (1) |
| Ox10F | Port 1, Dropped Packets Counter (2) |
| 0x110 | Port 1, Dropped Packets Counter (3) |
| 0x111 | |
| . | . |
| . | . |
| . | . |
| 0x2FF | Reserved |
| 0x300 | Local EEPROM Contents |
| . | . |
| . | . |
| . | . |
| 0x3FF | Local EEPROM Contents |

Prior to insertion of the management packet 70 into the IPG 80, the active idle signals 83 comprising the IPG 80 can be read by the sending device to verify that the IPG 80 includes only idle bytes or non-data. The sending device then inserts the management packet 70 (which in the embodiment shown includes six bytes) into the IPG 80 (which in the embodiment shown includes at least twelve bytes) by replacing the corresponding idle bytes with bytes of the management packet 70. The receiving device removes the bytes of the management packet 70 and reconstitutes the original IPG 80 to comprise only active idle signals 83. Note that the original IPG 80 can be a default or otherwise known set of active idle signals 83.

As previously discussed, the management packet 70 is transmitted during the IPG 80. To minimize and eliminate interference with user data, the management packet 70 can be transmitted directly following a payload data (e.g., Ethernet) packet. If there is no Ethernet traffic to be inserted therebetween, then management packets 70 may be generated at any time (e.g., after the first three idle bytes) during the idle period. If user data is received (or detected, typically by a non-match of the idle signal at the physical layer) during transmission of the management packet, then the transmission of the management packet is terminated or otherwise aborted immediately to allow the Ethernet traffic to flow through unaltered.

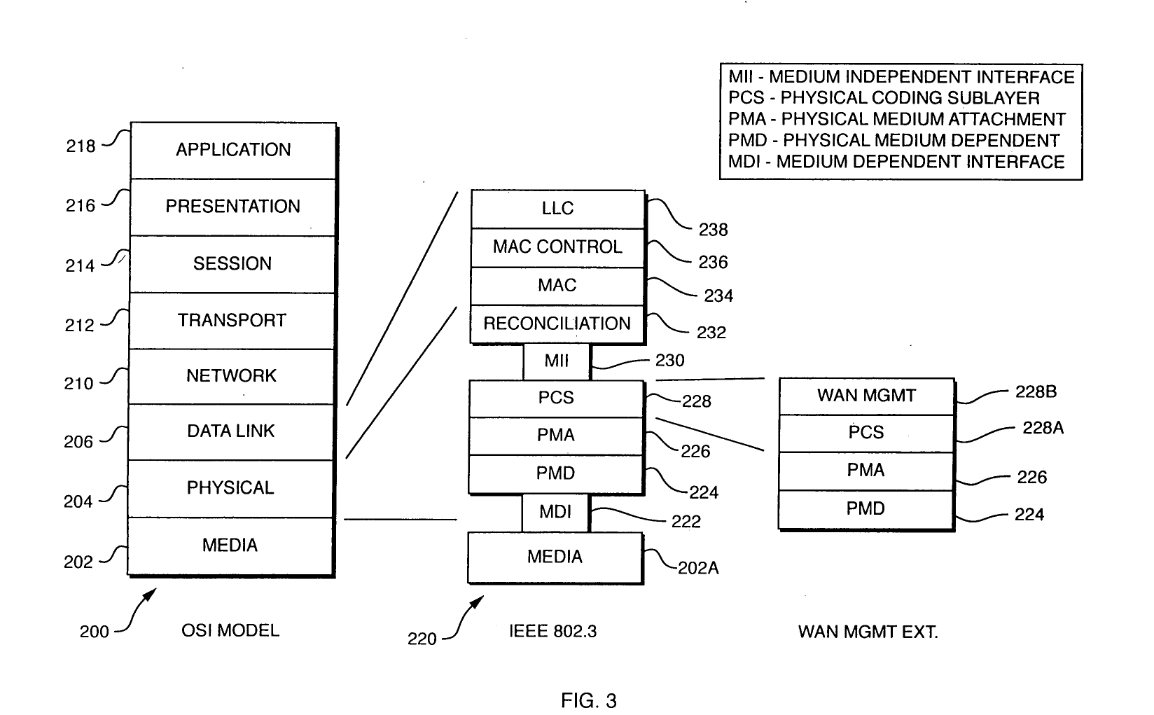

FIG. 3 illustrates the signalling hierarchy including the location of WAN management signalling in accordance with one embodiment of the present invention. In particular, the OSI hierarchical model 200 of packet data and the corresponding IEEE 802.3 standard model 220 are shown. Since the management packet 70 appears in the IPG 80, the management frame 70 is separated early in the OSI model, at the physical layer 204 (as compared to conventional management techniques which insert and extract management data at higher layers (typically transport 212 or session 214 layers.) The corresponding IEEE 802.3 standard model 220 provides sublayers, including a physical coding sublayer (PCS) 228. In accordance with this embodiment of the present invention, the physical coding sublayer 228 is effectively extended to include both PCS 228A and WAN management (WAN MGMT) sublayer 228B. Transacting (e.g., inserting or removing) the management frame 70 occurs within the WAN management sublayer 228B. Thus, the existence of the management frame 70 is invisible above the OSI physical layer 204.

Methodology

FIG. 4A and FIG. 4B illustrate communication sequences between local and remote devices in accordance with one embodiment of the present invention. As previously noted, the CPU 53 is included in the network controller 52 of the locally managed device 54.

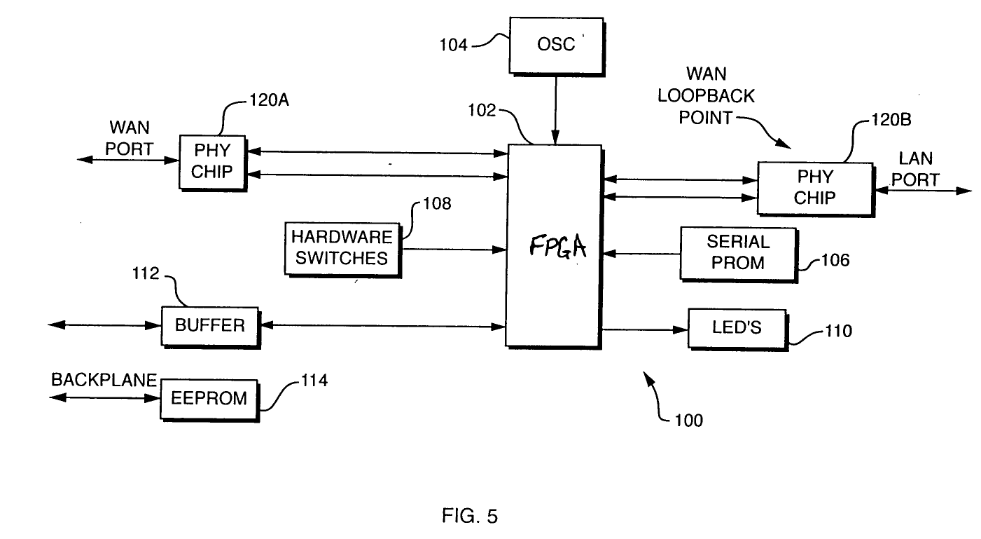

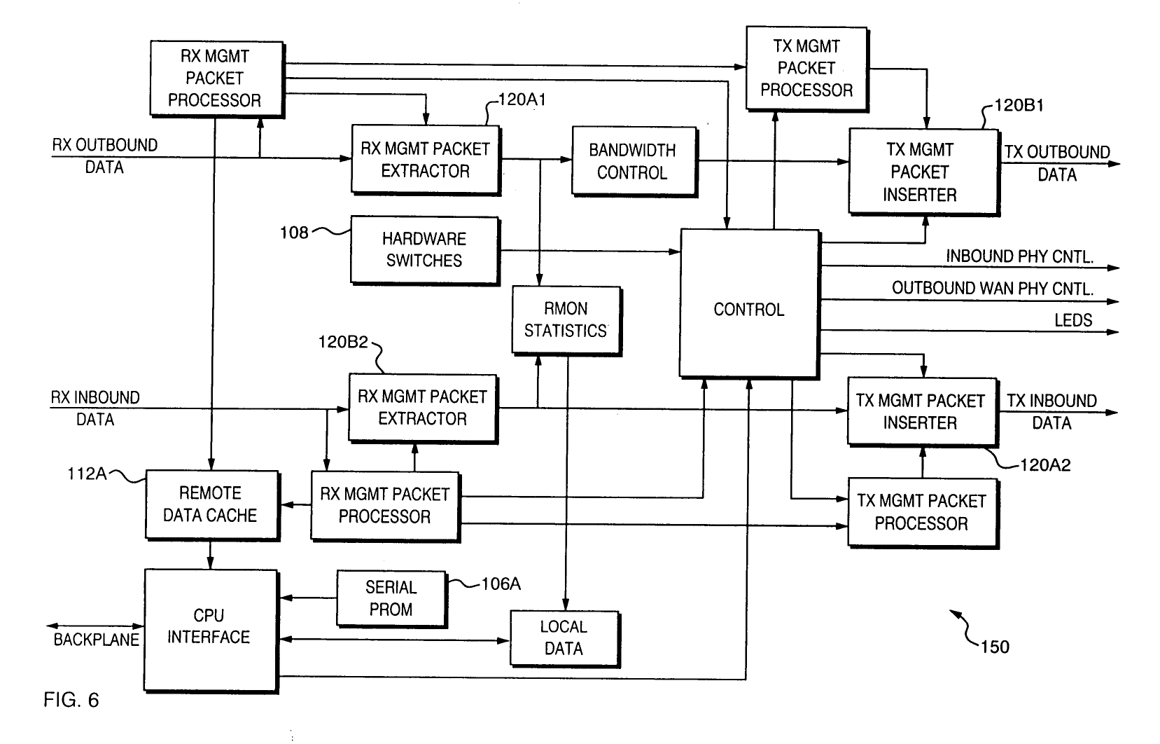

Upon power up, the locally managed device 54 establishes the presence of a remotely manageable device 56 by querying the local interface for remote device information or other known discovery techniques. Staging registers/caches and transmit/receive state machines (e.g., programmable logic) or other suitable processors (e.g., microcontroller configured with a processor, memory, I/O capability, and a number of programmed processes such as packet assembly/disassembly and error coding/decoding) can be used to carry out the illustrated protocol. Example architectures will be discussed in more detail with reference to FIGS. 5 and 6.

In FIG. 4A, the locally managed device 54 issues a write request 91 to the remote device 56A. The write request 91 is packaged into a management packet 70 and transmitted in the management channel (in the IPG between data packets). In one such example, only one write request 91 is outstanding at any specific time. After a predetermined time-out, the locally managed device 54 can be programmed or otherwise configured (via CPU 53) to issue a duplicate or new write request if no write response 92 is received from the remote device 56A. Note that memory locations and registers of the remote device 56A can be accessed with the write command. Further note that the write command enables over-ride of the local switch setting on the remote device 56A (e.g., through direct register access).

Also shown in FIG. 4A is an alarm notification sequence. In particular, alarm notification 94 is issued by a remote device 56A, for example, in response to the contents of an alarm register changing unexpectedly or in response to the occurrence of some other alarm event. The alarm notification 94 is packaged into a management packet 70 and transmitted in the management channel. There are a number of alarms that can be provided.

For example, the remote device 56A may be configured with a number of environmental sensors that provide real-time monitoring of the device's temperature and each of its power supplies. In particular, a trap can be enabled (e.g., via software) to send an alarm notification 94 if the reading of a sensor falls outside a set range. When the alarm notification is received at the locally managed device 54 (by way of the management channel), the network operator will be informed of a potential problem. Such alarm notification enables remote monitoring of the remote device's 56A temperature and voltage levels. Note that alarm indications can be sent as specific data words, each having a pre-assigned meaning.

Another example remote event that can be monitored is the input and output power levels of a singlemode fiber optic port (assuming that the remote device 56A has such a port and diagnostic capabilities including power measurement). If a measured power reading is out of the pre-defined range, then an alarm notification can be sent to the network administrator (via the locally managed device 54) so that appropriate action can be taken (e.g., replace failing remote device 56A). Note that available diagnostic information can be included in the alarm notification packet. Further note that ports can be designated, for instance, as long haul and extend long haul, where the power requirements for different type ports are set accordingly.

In FIG. 4B, the locally managed device 54 issues a memory (EEPROM) read request 95, so as to read from the memory of the remote device 56A the following type of information: device serial number, model number, hardware revision, date of manufacturing, connector type, and other pre-stored information relevant to the device 56A. A read response 92 is then provided by the device 56A (assuming the device is enabled and functioning properly).

The locally managed device 54 is also configured to issue a register read request 92, so as to read the accessible registers and counters of the remote device 56A. The targeted registers generally store pertinent information relevant to the remote device 56A, such as its link status, alarm status, and remote monitoring (RMON) and Ethernet statistic. A read response 92 is then provided by the device 56A (assuming the device is enabled and functioning properly).

In one example embodiment, and with reference to FIG. 1, the locally managed device 54 operates in conjunction with the SNMP control 58 to provide remote management statistics associated with the remote device 56A. The SNMP control 58 can be, for example, the NetBeacon or WebBeacon products offered by Metrobility Optical Systems, Inc. in Merrimack, N.H. The locally managed device 52 and the remote device 56A can be implemented with Metrobility's Radiance Access Line Cards. Here, each port on the cards supports the complete RMON Group 1 statistics outlined in RFC 1757. In addition, for the fiber port of the cards, the Ethernet statistics shown in Table 2 can be reported. For copper ports, the port link status can be reported.

TABLE 2

| Statistic Name | Description |
|---|---|
| Port Link Status | Indicates whether or not the port has a valid link. |
| Link Transition | Number of times link was lost since power-up. The |
| Counter | value is 0 after the card is reset, even without a link. |
| Management | Number of management packets 70 received. |
| Counter | |
| Discovery | Number of remote devices 56 discovered on the |
| Count | network. |

Example read/write commands and notifications illustrated in FIGS. 4A and 4B that could be specified in the CMD 72 portion of the management packet 70 are summarized in Table 3.

TABLE 3

| Command/ | |
|---|---|
| Response | Purpose |
| Read | Issued by the locally managed device 54 to read the |
| Command | contents of a location on a remote device 56. Data 75 of |
| 93 | the command packet 70 is ignored on Read Commands. |
| Write | Issued by the locally managed device 54 to write a value to |
| Command | a location on a remote device 56. Data 75 of the command |
| 91 | packet 70 contains the 8-bit value being written. |
| Response | Issued by a remote device 56 in response to either a Read |
| Notification | or Write command. CMD 72 of the response packet 70 |
| 92 | includes the register location being read or contents after |
| | any write operation has occurred. |
| Alarm | Issued by a remote device 56 in response to the contents of |
| Notification | an alarm register changing unexpectedly. CMD 72 of the |
| 94 | alarm notification packet 70 includes the register location |
| | and contents after any change has occurred. |
| Bandwidth | Issued by the locally managed device 54 to allocate a |
| Allocation | particular bandwidth scheme. Data 75 of the command |
| Command | packet 70 directly specifies or otherwise contains the 8-bit |
| | code that corresponds to the selected scheme. |
| Maximum | Issued by the locally managed device 54 to set maximum |
| Burst Size | burst size. Data 75 of the command packet 70 specifies the |
| Command | selected burst size. |
| Loopback | Issued by the locally managed device 54 to enable loopback |
| Mode | mode at a remote device. |
| Command | |

Various packet structures and syntax can be used here as will be apparent in light of this disclosure. Thus, the various portions of the management packet and how they are structured and used depends on the particular application and implementation details. Other commands are also possible here. For instance, and as shown in Table 3, bandwidth for a particular port can be provisioned, either locally or remotely, with a bandwidth command included in the management packet. Also, a command to set the maximum burst size (locally or remotely) can be provided. Also, a command to enable loopback mode (locally or remotely) can be provided.

Architecture

FIG. 5 is a block diagram of the board level implementation configured in accordance with one embodiment of the present invention. This implementation could be, for example, a media converter line card (e.g., copper to fiber interface) deployed as the locally managed device 54 of FIG. 1. Note that the remote device 56 of FIG. 1 can be similarly configured. Various other embodiments and implementation details will be apparent in light of this disclosure, as the principles of the present invention can be implemented in hardware, software, firmware, and combinations thereof (e.g., such as an FPGA or purpose built semiconductor, or one or more processes executing in a microcontroller).

As can be seen, the board 100 includes a Field Programmable Gate Array (FPGA) 102, which could also be an Application Specific Integrated Circuit (ASIC) or other suitable processing environment that can be configured to carry out management functions as described herein. The clock oscillator 104, serial PROM 106, user option switches 108, signal LEDs 110, and controller backplane interface and data buffer 112 are connected to the FPGA 102 to provide the structure and functionality as will be apparent in light of this disclosure. The data buffer 112 and an EEPROM 114 communicate with the controller 52 of the locally managed device 54.

The physical layer (PHY) circuits 120A and 120B communicate between WAN and LAN media (e.g., copper-to-copper, copper-to-fiber, fiber-to-copper, and fiber-to-fiber), and provide access to the management channel (e.g., idle signals during the IPG) as described herein.

The internal structure of FPGA 102 and its interaction with componentry of FIG. 5 is discussed in reference to FIG. 6. As can be seen, the PHY element 120A includes a receive (RX) management packet extractor module 120A1 and a transmit (TX) management packet inserter module 120A2, which provide the FPGA 102 access to the incoming and outgoing management packets 70 on the WAN port of the board. Likewise, the PHY element 120B includes a TX management packet inserter module 120B1 and a RX management packet extractor module 120B2, which provide the FPGA 102 access to the outgoing and incoming management packets 70 on the LAN port of the board. Similar functionality and architecture applies to each port.

For example, packet data received at either of the WAN or LAN port is provided to the corresponding RX management packet processor, which determines if a management packet 70 is available (as opposed to idle IPG data). If not, the packet data is passed through to the corresponding TX management packet processor to be forwarded in normal fashion. In this case, the TX management packet inserter inserts the original idle data received in the packet, or does nothing (i.e., the idle data of the IPG is left undisturbed).

If a management packet 70 is included, the packet data is passed through to the corresponding RX management packet extractor. The extracted management packet data is processed by the corresponding RX management packet processor, which provides the extracted management information (e.g., read/write command and address information) to the control module so that the management request can be carried out. Note that the control module and management functionality can also be accessed by a local processor via the CPU interface, which operatively couples the control module to the backplane. Thus, both remote and local access is provided. Registers included in the local data module can be accessed as necessary in carrying out the various management functions, as previously discussed with reference to Table 1.

An RMON statistics module is also provided, as shown in FIG. 6, for carrying out a read request for remote monitoring purposes. In the case of such a read request, the read RMON statistics are provided to the TX management packet inserter which provides a response management packet in the IPG. This management packet 70, which includes the requested data (e.g., RMON Group 1 and select Ethernet statistics), is then transmitted back to the requesting device by the corresponding PHY circuit 120. Alternatively, the statistics can be read locally via the CPU interface.

A bandwidth control module is also provided, as shown in FIG. 6. This module allows the amount of incoming and outgoing data that can be carried over the network to be specified. For example, the RX and TX bandwidth can be set through a copper port (assuming a twisted-pair transition medium, which is generally bandwidth limited, and a likely candidate for a flexible bandwidth provisioning scheme) in 1 Mbps increments from 1 to 100. Note that the TX and RX bandwidths can be set to the same rate if equal input and output bandwidth is so desired, but they need not be the same. When the RX bandwidth is set, the allocation is applied to the traffic received on the corresponding port. Likewise, when the TX bandwidth is set, the allocation is applied to the traffic transmitted on the corresponding port.

The bandwidth can be set, for example, using a bandwidth allocation command included in a received management packet 70. The command packet could include in its data 75 field a code that specifies a particular port and the desired outgoing and/or incoming bandwidth. The code can then be applied to programmable logic to change the bandwidth allocation accordingly. Alternatively, a look-up table specifying a number of particular bandwidth schemes indexed by codes (e.g., 8-bit code included in management packet, thereby providing for a total of 255 bandwidth allocation schemes, with code 0000 indicating no change in bandwidth allocation) could be included in or otherwise accessible by the bandwidth control module. The bandwidth control module can then be configured to provision the bandwidth according to the scheme associated with the index code that matches the code in the command.

In addition to bandwidth allocation, network performance can be improved by choosing the maximum burst size in each direction. For instance, to accommodate for fluctuations that commonly occur in network traffic, the board 100 can be configured with an option to specify maximum burst size permitted in each direction. Such a feature would allow customers to have full access to their channel bandwidth until the burst threshold is reached. At that point the channel bandwidth is restricted for a period of time, depending on the bandwidth setting, until more data packets or frames are accepted. Such a feature is thus beneficial to a customer who can take advantage of a communication channel's full bandwidth, as long as the data burst size can be quantified and the burst is followed by a period of inactivity.

The maximum burst size can be set, for example, using a maximum burst size command included in a received management packet 70. The command packet could include in its data 75 field a code that specifies a particular direction and the desired maximum burst size. The code can then be applied to programmable logic to change the maximum burst size accordingly. Alternatively, a look-up table as discussed in reference to the bandwidth provisioning option could be used. Note that the maximum burst size parameter can be set individually or integrated into the overall bandwidth provisioning scheme.

Further note from FIG. 5 that a loopback option can also be provided by the board 100. Loopback enables a remote port to return its incoming data back to the sender for testing and diagnostic purposes. Note that the return of the loopback packet is performed while the remote device continues to receive and transmit management packets 70. Further note that the management packets 70 need not be looped back to the sender; only the data packets are returned. When loop back is enabled on a port, its incoming data is transmitted through the entire circuitry of the board 100, not just the port in the loopback mode. This allows the entire circuit to be tested. RMON statistics can be incremented on both ports of the board 100, even though the physical interface on the port without loopback is neither transmitting nor receiving traffic (i.e., when one port on a line card is enabled for loopback, the other port is disabled).

The loopback mode can be set, for example, using a loopback mode command included in a received management packet 70. When the command packet is received at the RX management packet processor and extractor modules of a particular PHY layer 120, the loopback command is detected, and the packet is processed for loopback (e.g., set destination address of the loopback packet to the address of the sending device). The loopback packet is then provided to the TX management packet processor and inserter modules for transmission back to the sending device. One example loopback technique that can be implemented here is described in U.S. application Ser. No. ______(not yet known), filed May 24, 2004, titled “Logical Services Loopback”<attorney docket number MET002-US>. This application is herein incorporated in its entirety by reference. However, conventional loopback techniques may be employed as well.

The foregoing description of the embodiments of the invention has been presented for the purposes of illustration and description. It is not intended to be exhaustive or to limit the invention to the precise form disclosed. Many modifications and variations are possible in light of this disclosure. For instance, other structural implementations of adding signalling at the physical or MAC layer of the sending device and recovering (and optionally removing) signalling in the receiving device at the physical or MAC layer is within the scope of the present invention. Also, the network media is not limited to twisted-pair, fiber-optic, coaxial cable, etc., and includes any media, including wireless, by which the network may be configured and made operable with appropriate PHY elements 120A and 120B. It is intended that the scope of the invention be limited not by this detailed description, but rather by the claims appended hereto.

1. A line card apparatus for carrying out remote management over a network without using payload data bandwidth, comprising:
a first media physical layer connection device adapted to transmit over a first media payload data packets with inter-packet gaps therebetween; and
a management packet inserter module adapted for inserting management packets into the inter-packet gaps, thereby providing a management channel for carrying out remote device management without impacting payload data bandwidth.

2. The apparatus of claim 1 wherein the first media physical layer connection device is further adapted to receive remotely transmitted payload data packets with inter-packet gaps therebetween, the apparatus further comprising:
a management packet extractor module adapted for extracting management packets from the inter-packet gaps.

3. The apparatus of claim 1 wherein the apparatus enables communication between the first media and a second media, the apparatus further comprising:
a second media physical layer connection device in communication with the first media physical layer connection device, and adapted to transmit second media payload data packets with inter-packet gaps therebetween.

4. The apparatus of claim 3 further comprising:
a second management packet inserter module adapted for inserting management packets into the inter-packet gaps between the second media payload data packets, thereby providing a second management channel for carrying out management of one or more remote devices associated with the second media.

5. The apparatus of claim 3 wherein the second media physical layer connection device is further adapted to receive second media payload data packets with inter-packet gaps therebetween, the apparatus further comprising:
a second management packet extractor module adapted for extracting management packets from the inter-packet gaps between the second media payload data packets.

6. The apparatus of claim 1 wherein the payload data packets and inter-packet gaps therebetween comply with IEEE 802.3 standards, whether carrying user data, idle data, or management data.

7. The apparatus of claim 1 wherein the management packet includes a command portion that enables at least one of the following: loopback mode at a remote device, alarm notification, remote monitoring of statistics, and remote monitoring of remote device parameters.

8. The apparatus of claim 1 wherein the management packet includes a command portion that enables remote monitoring of at least one of a remote device's temperature and power supplies.

9. The apparatus of claim 1 wherein the management packet includes a command portion that enables remote monitoring of at least one of a remote device's transmit and receive power.

10. The apparatus of claim 1 wherein the management packet includes a command portion that enables at least one of writing data to a remote device and reading data from a remote device.

11. The apparatus of claim 1 wherein the management packet includes a command portion that enables at least one of bandwidth provisioning and adjustment of maximum burst size associated with a particular communication port on the network.

12. An apparatus for carrying out remote management over a network without using payload data bandwidth, comprising:
a first media physical layer connection device adapted to transmit and receive first media payload data packets with inter-packet gaps therebetween;
a second media physical layer connection device in communication with the first media physical layer connection device, and adapted to transmit and receive second media payload data packets with inter-packet gaps therebetween; and
one or more modules adapted to use the inter-packet gaps to provide a management channel for carrying out remote device management without impacting payload data bandwidth.

13. The apparatus of claim 12 wherein the management channel enables alarm reporting by a remote device.

14. The apparatus of claim 12 wherein the management channel enables loopback mode at a remote device.

15. The apparatus of claim 12 wherein the management channel enables remote monitoring of statistics.

16. The apparatus of claim 12 wherein the management channel enables monitoring of remote device parameters including at least one of: temperature, transmit power, receive power, and power supply voltages.

17. The apparatus of claim 12 wherein the management channel enables at least one of writing data to a remote device and reading data from a remote device.

18. The apparatus of claim 12 wherein the management channel enables at least one of bandwidth provisioning and adjustment of maximum burst size associated with a particular communication port on the network.

19. An apparatus for carrying out remote management over a network without using payload data bandwidth, comprising:
a first physical layer circuit configured to provide access to a first management channel allocated during inter-packet gaps that exist between payload packets processed by the first physical layer circuit; and
a second physical layer circuit configured to provide access to a second management channel allocated during inter-packet gaps that exist between payload packets processed by the second physical layer circuit;
wherein each of the first and second management channels is for carrying out remote device management without impacting payload data bandwidth.

20. The apparatus of claim 19 wherein the first physical layer circuit couples to a first media and the second physical layer circuit couples to a second media, and the apparatus operates as media converter.
